(19) United States
(12) Patent Application Publication
(10) Pub. No.: US 2008/0029890 A1
(43) Pub. Date: Feb. 7, 2008

(54) EMBEDDED CHIP PACKAGE PROCESS AND CIRCUIT BOARD WITH EMBEDDED CHIP

(75) Inventor: David C. H. Cheng, Taoyuan County (TW)

Correspondence Address: J C PATENTS, INC., 4 VENTURE, SUITE 250, IRVINE, CA, 92618, US

(73) Assignee: UNIMICRON TECHNOLOGY CORP., Taoyuan (TW)

(21) Appl. No.: 11/623,562

(22) Filed: Jan. 16, 2007

(30) Foreign Application Priority Data
Aug. 3, 2006 (TW) 95128461

(51) Int. Cl. H01L 23/52

(52) U.S. Cl. 257/739

(57) ABSTRACT

An embedded chip package process is provided. First, a chip is connected to a first circuit layer on a carrier, and then a cover plate is pressed onto a dielectric material layer to make the chip embedded in the dielectric material layer so that a circuit board with an embedded chip is formed. The chip has at least a bump electrically connected to a bonding pad of the first circuit layer through a solder. With enhanced reliability and alignment in chip bonding, the flip-chip bonding process replaces the conventional method of Laser drilling and circuit fabrication.

### CROSS-REFERENCE TO RELATED APPLICATION

This application claims the priority benefit of Taiwan application serial no. 95128461, filed Aug. 3, 2006. All disclosure of the Taiwan application is incorporated herein by reference.

### BACKGROUND OF THE INVENTION

1. Field of the Invention

The present invention relates to a chip package process and its structure, and more particularly, to an embedded chip package process and its structure.

2. Description of Related Art

With continuous innovations in electronic technologies in recent years, more personalized and functionally improved hi-tech electronic products continue to appear in the market. Moreover, the upcoming trend is to design lighter and more compact products. In general, a circuit substrate is disposed inside these electronic products. The circuit substrate carries a single chip or multiple chips to serve as the data processing unit of the electronic product. However, disposing one or more chips on the circuit substrate often increases the carriage surface area. Therefore, embedding the chips inside the circuit substrate has become a critical technique at the moment.

FIG. 1 is a schematic cross-sectional view of a conventional circuit substrate with embedded chips. As shown in FIG. 1, the circuit substrate 10 includes a substrate 100, a plurality of chips 110, a dielectric layer 120, a circuit layer 130, an oxidation-resistant layer 140 and a solder mask layer 150. The chips 110 are disposed on the substrate 100 and the dielectric layer 120 is formed over the substrate 100 to cover the chips 110. In addition, the bonding pads 112 of each of the chips 110 are connected to the circuit layer 130 through Laser-drilled conductive holes 122. Furthermore, the circuit layer 130 is connected to the corresponding conductive plugs 132 to form a circuit substrate 10 with embedded chips 110.

In the foregoing circuit substrate 10, the chips 110 are disposed on the same plane surface. If the number of chips 110 is increased, the area of the substrate 100 must increase correspondingly. Moreover, the alignment of the conductive holes 122 is easily shifted when fabricated using Laser drilling, thereby leading to a lower yield.

### SUMMARY OF THE INVENTION

Accordingly, at least one objective of the present invention is to provide an embedded chip package process that utilizes flip-chip bonding technique to increase the yield of chip bonding.

At least another object of the present invention is to provide a circuit substrate with embedded chip that utilizes a flip-chip package to increase the yield of chip bonding.

To achieve these and other advantages and in accordance with the purpose of the invention, as embodied and broadly described herein, the invention provides an embedded chip package process comprising the following steps. First, a carrier and a metal plate are provided and the metal plate is disposed on the carrier. The metal plate is patterned to form a first circuit layer on the carrier, and the first circuit layer includes at least a bonding pad. A solder layer is formed on the bonding pad. A chip is disposed on the carrier. The chip has at least a bump electrically connected to the bonding pad through the solder layer. A dielectric material is disposed over the circuit layer so that the chip is embedded within the dielectric material layer. A cover plate and a second circuit layer are provided. The second circuit layer is disposed on the cover plate. A pressing process is performed to press the second circuit layer on the cover plate into the dielectric material layer.

According to one embodiment of the present invention, the foregoing dielectric material layer includes a plastic film formed by plasticizing prepreg resin material. In addition, the plastic film has an opening that corresponds to the chip and the chip is located within the opening when the plastic film covers the circuit layer.

According to one embodiment of the present invention, after the step of covering the circuit layer with the foregoing dielectric material layer, further includes a step of heating to cure the dielectric material. After the step of curing the dielectric material, further includes a step of removing the carrier and the cover plate. Furthermore, after the step of curing the dielectric material, further includes a step of forming at least a through hole in the dielectric material layer and filling the through hole with conductive paste. The two ends of the through hole are connected to the first circuit layer and the second circuit layer respectively. Moreover, a first contact is disposed on the first circuit layer corresponding to one end of the through hole and a second contact is disposed on the second circuit layer corresponding to the other end of the through hole. In addition, the first contact and the second contact are electrically connected through the conductive paste.

According to one embodiment of the present invention, the foregoing second circuit layer further includes a shielding layer covering the dielectric material layer above the surface of the chip to prevent interference by electromagnetic waves.

According to one embodiment of the present invention, the foregoing carrier includes a metal plate or an insulation plate, and the metal plate includes a resin coated copper plate. Furthermore, the cover plate includes a metal plate or an insulation plate, and the second circuit layer includes a patterned resin coated copper layer.

The present invention also provides a circuit substrate with embedded chip. The circuit substrate includes a substrate, an embedded device and a shielding layer. The substrate includes a first circuit layer, a dielectric layer and a second circuit layer. The first circuit layer and the second circuit layer are located on the two opposite surfaces of the dielectric layer. The dielectric layer has a conductive through hole that electrically connects the first circuit layer and the second circuit layer. Furthermore, the embedded device is embedded in the dielectric layer and electrically connected to the first circuit layer. In addition, the shielding layer covers the surface of the dielectric layer facing the embedded device.

According to one embodiment of the present invention, the first circuit layer has a first contact correspondingly disposed at one end of the conductive through hole and the second circuit layer has a second contact correspondingly disposed at the other end of the conductive through hole. Moreover, the first contact and the second contact are electrically connected through the conductive through hole.

According to one embodiment of the present invention, the foregoing shielding layer includes a copper layer, a metallic glass layer, a tin layer or a wave-absorbing material layer. Moreover, the shielding layer and the second circuit layer can be fabricated together or respectively.

According to one embodiment of the present invention, the foregoing embedded device includes a chip. The chip has at least a bump and the first circuit layer has a corresponding bonding pad electrically connected to the bump. In addition, the embedded device comprises capacitors, resistors or inductors.

In the present invention, high yield flip-chip bonding technique is used. The chip is connected to the first circuit layer on the carrier and then a cover plate is pressed onto the dielectric material so that the chip is embedded within the dielectric material layer. This replaces the Laser drilling and circuit processing in a conventional embedded chip. Hence, the yield of the chip bonding is increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional circuit substrate with embedded chips.

FIGS. 2A through 2G are schematic cross-sectional views showing the steps in an embedded chip package process according to one embodiment of the present invention.

FIG. 3 is a schematic cross-sectional view of a chip package structure according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

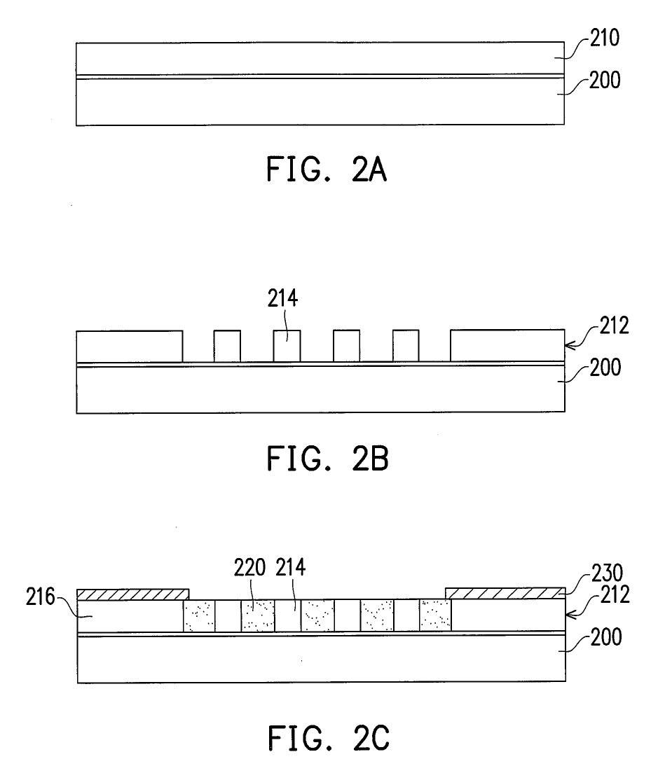

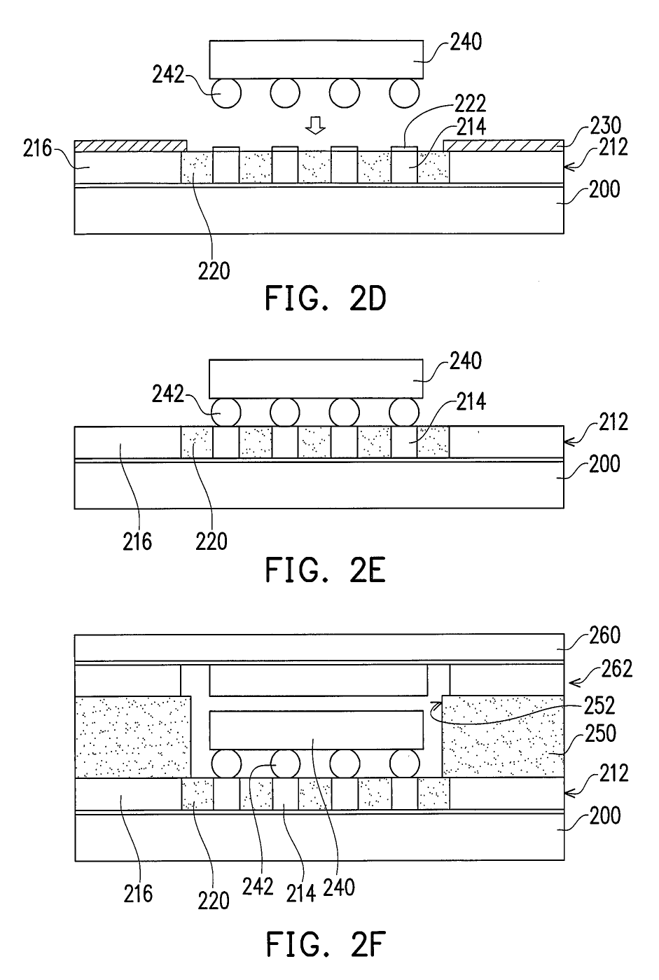

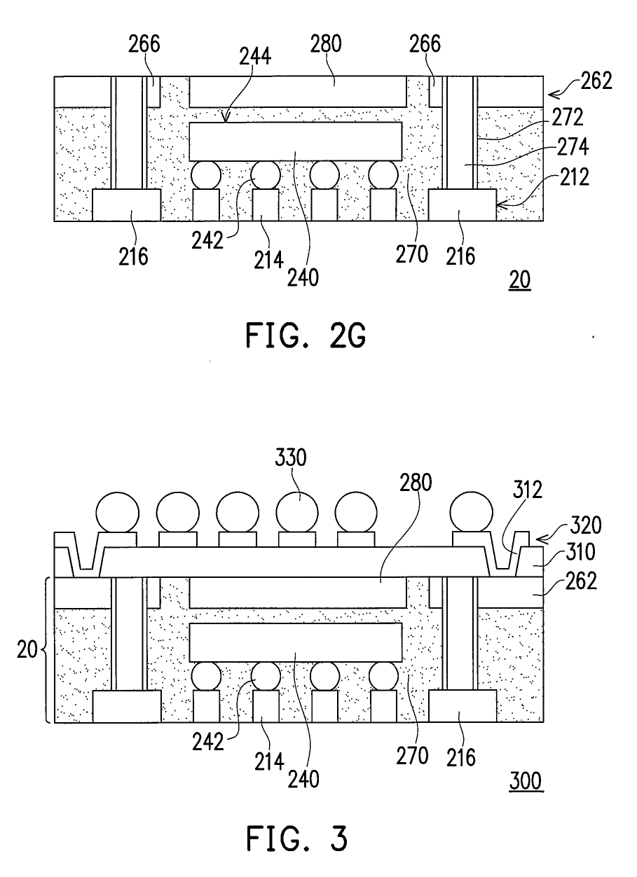

FIGS. 2A through 2G are schematic cross-sectional views showing the steps in an embedded chip package process according to one embodiment of the present invention. FIGS. 2A through 2E show the steps for disposing chips on a carrier using the flip-chip bonding technique, and FIGS. 2F and 2G show the steps of embedding the chip in a dielectric material layer and performing a pressing process to produce the correct form. Although a single chip is used in the packaging process, this is used as an example for illustration only. The present invention can also be applied to a multi-chip packaging process with a subsequent cutting to produce single chip packages or multi-chip packages.

As shown in FIGS. 2A and 2B, a carrier 200 and a metal plate 210 are provided. Next, the metal plate 210 is patterned to form a first circuit layer 212. The carrier 200 is, for example, a metal plate or an insulation plate that can provide sufficient strength and support. However, the carrier 200 can be a flexible thin film or plastic film for supporting the metal plate 210. The metal plate 210 is, for example, a resin coated copper foil or other conductive plate attached to the carrier 200 for performing patterning steps such as exposure, development and etching so that the first circuit layer 212 has at least a bonding pad 214. The number of bonding pads 214 is based on the actual loading of the input/output signals. In the present embodiment, the metal plate 210 can be patterned using a conventional dry etching or wet etching process to form the required first circuit layer 212.

As shown in FIGS. 2C and 2D, an insulation layer 220 is formed on the carrier 200 and then a removable dry film 230 is formed over the carrier 220 in preparation for a subsequent plating or printing process. The insulation layer 220 may expose the upper surface of the bonding pads 214 of the first circuit layer 212. The dry film 230 may cover the other surface (for example, the surface of the first contact 216) of the first circuit layer 212 so that a solder material layer 222 is plated on the upper surface of the bonding pads 214. In the present embodiment, the solder material layer 222 is, for example, a lead-tin alloy layer or other low melting point alloy layer. The purpose of forming the solder material layer 222 on the bonding pads 214 is to enhance the bonding strength and alignment accuracy between the bumps 242 on a chip 240 and the bonding pads 214. Obviously, a silver paste printing process may be performed to form a solder material layer 222 on the bonding pads 214 for serving the same function as the one formed by a plating process.

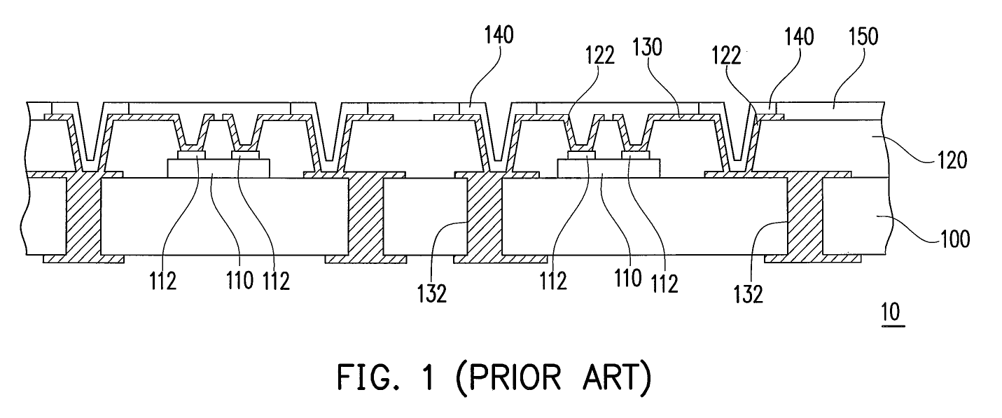

As shown in FIG. 2E, the dry film 230 is removed. Next, the chip 240 is disposed on the first circuit layer 212 using a flip-chip bonding technique. The bumps 242 on the chip 240 and the bonding pads 214 are connected to each other through the solder material layer 222, with the solder material layer 222 serving as an electrical signal transmission medium. Because the solder material layer 222 can prevent a shift in the alignment of the bumps 242 and enhance the bonding strength, the reliability and yield of the flip-chip bonding is increased. Moreover, the high-yield flip-chip bonding technique of connecting the chip 240 to the first circuit layer 212 of the carrier 200 can avoid the conventional Laser drilling process and the process of forming the circuit layer 130 with connection to the embedded chip 110 as shown in FIG. 1.

As shown in FIG. 2F, a dielectric material layer 250 is deposited and a cover plate 260 is pressed on the dielectric material layer 250 so that the chip 240 is embedded within the dielectric material layer 250. The dielectric material 250 is fabricated using an insulating material, for example, prepreg bismaleimide triazine (BT) resin or polypropylene (PP) resin. The dielectric material layer 250 can be fabricated by performing a polymerization reaction to attain a certain degree of plasticity, thereby forming a plastic film. Moreover, before the dielectric material layer 250 is reacted to form a plastic film in a polymerization reaction, glass fibers may be added, as an option, to enhance the strength and supportability of the dielectric material layer 250. In the present embodiment, when the dielectric material layer 250 is still a prepreg plastic film over the first circuit layer 212, a suitable opening 252 capable of accommodating the chip 240 is pre-fabricated in the plastic film at a location corresponding to the chip 240. The purpose of pre-fabricating the opening 252 is to avoid the plastic film pressing against the chip 240 in a subsequent pressing process and cause some damage to the chip 240.

When the chip 240 is embedded within the dielectric material layer 250, the cover plate 260 is evenly pressed onto the dielectric material 250 so that the chip 240 and its bumps 242 are completely encapsulated within the dielectric material 250. Since the dielectric material layer 250 has not been cured to produce a fixed form, a heat treatment is performed to induce molecular cross-linking and thereby cure the dielectric material layer 250.

It should be noted that a second circuit layer 262 can be pre-fabricated on the cover plate 260 in addition to using the cover plate 260 for applying pressure on the dielectric material layer 250. The method of forming the second circuit layer 262 is similar to the fabrication of the first circuit layer 212 on the carrier 200 as shown in FIGS. 2A and 2B so that a detailed description is omitted. The cover plate 260 is a strengthened and supportive metal plate or insulation plate and the second circuit layer 262 is a patterned resin coated copper layer or other metal layer, for example. When the cover plate 260 presses on the dielectric material layer 250, the second circuit layer 262 is pressed onto the dielectric material layer 250 as shown in FIG. 2F.

Next, as shown in FIG. 2G, after the dielectric material layer 250 is completely cured to be a cured dielectric- layer 270, the carrier 200 and the cover plate 260 can be removed by lifting them off or performing other peeling techniques. Hence, only the first circuit layer 212 and the second circuit layer 262 are retained on the opposite surfaces of the cured dielectric layer 270, thereby forming a circuit substrate 20 with embedded chip 240. The cured dielectric layer 270 can also be Laser-drilled to form at least a through hole 272 having two ends connected the first circuit layer 212 and the second circuit layer 262 respectively. In addition, the first circuit layer 212 has a first contact 216 correspondingly disposed at one end of the through hole 272 and the second circuit layer 262 has a second contact 266 correspondingly disposed at the other end of the through hole 272. Furthermore, the first contact 216 and the second contact 266 are electrically connected through the conductive paste 274 inside the through hole 272 so that signal can be transmitted between them.

It should be noted that, aside from having a first and a second circuit layers 212 and 262 to transmit electrical signals to and from the chip 240 or other devices, the circuit substrate 20 might further include a shielding layer 280. The shielding layer 280 covers a surface of the cured dielectric layer 270 above the chip 240 and is set apart from the back surface 244 of the chip 240 by a gap or in contact with the back surface 244 of the chip 240 (not shown). The area of the shielding layer 280 is preferably greater than or equal to the area of the chip 240 so as to stop any electromagnetic wave incident on the chip 240 and prevent electromagnetic wave from interfering with the normal operation of the chip 240. In the present embodiment, the shielding layer 280 can be a copper layer or any other highly conductive metallic layer. In addition to the copper layer, the shielding layer 280 can be fabricated by a metallic glass layer, a tin layer or a wave-absorbing material layer. Furthermore, the shielding layer 280 can also be fabricated in the process of patterning the second circuit layer 262 or fabricated independently on the cover plate 260 by attachment and then pressed into the dielectric material layer 250.

Finally, in the chip package structure 300 as shown in FIG. 3, the fabrication of at least a circuit layer and solder balls on the circuit substrate 20 shown in FIG. 2G is illustrated. The dielectric layer 310 and the surface circuit layer 320 are sequentially formed on the circuit substrate 20 through lamination, and the surface circuit layer 320 are electrically connected to the second contact 266 of the second circuit layer 262 through the conductive hole 312 in the dielectric layer 310. In addition, a plurality of solder balls 330 can be disposed on the surface circuit layer 320 to form a ball grid array embedded chip package structure 300.

Besides the embedded chip, the present embodiment can also be applied to the package and structure of other embedded devices, for example, passive devices such as capacitors, resistors and inductors instead of the foregoing chip 240 to form a circuit substrate with embedded device. Since the fabrication process is identical to that shown in FIGS. 2A through 2G, a detailed description is omitted here.

In summary, the present invention utilizes a high yield flip-chip bonding technique to connect the chip to the first circuit layer on the carrier and press a cover plate onto the dielectric material so that the chip is embedded within the dielectric material layer. Therefore, the Laser drilling and circuit processing in a conventional embedded chip can be replaced to increase the yield of the chip bonding. In addition, a shielding layer is also disposed over the chip to prevent electromagnetic interference from affecting the operation of the chip and minimize noise produced by electromagnetic interference.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An embedded chip package process, comprising the steps of:
providing a carrier and a metal plate, wherein the metal plate is disposed on the carrier;
patterning the metal plate to form a first circuit layer on the carrier, wherein the first circuit layer comprises at least a bonding pad;
forming a solder material layer on the bonding pad;
disposing a chip on the first circuit layer, wherein the chip has at least a bump and the bump is electrically connected to the bonding pad through the solder material layer;
covering the first circuit layer with a dielectric material layer, wherein the chip is embedded within the dielectric material layer;
providing a cover plate and a second circuit layer, wherein the second circuit layer is disposed on the cover plate; and
performing a pressing process to press the second circuit layer on the cover plate into the dielectric material layer.

2. The embedded chip package process of claim 1, wherein the dielectric material layer comprises a plastic film formed by plasticizing prepreg resin material.

3. The embedded chip package process of claim 2, wherein the plastic film has an opening that corresponds to the chip and the chip is accommodated inside the opening when the plastic film covers the first circuit layer.

4. The embedded chip package process of claim 1, further comprising a step of heating to cure the dielectric material layer after the step of covering the first circuit layer with the dielectric material layer.

5. The embedded chip package process of claim 4, further comprising a step of removing the carrier after the step of curing the dielectric material layer.

6. The embedded chip package process of claim 4, further comprising a step of removing the cover plate after the step of curing the dielectric material layer.

7. The embedded chip package process of claim 4, further comprising a step of forming at least a through hole in the dielectric material layer and a step of filling the through hole with conductive paste so that the two ends of the through hole are respectively connected to the first circuit layer and the second circuit layer after the step of curing the dielectric material layer.

8. The embedded chip package process of claim 7, wherein the first circuit layer has a first contact correspondingly disposed at one end of the through hole and the second circuit layer has a second contact correspondingly disposed at the other end of the through hole so that the first contact and the second contact are electrically connected through the conductive paste.

9. The embedded chip package process of claim 1, wherein the second circuit layer further comprises a shielding layer covering a surface of the dielectric material layer facing the chip.

10. The embedded chip package process of claim 1, wherein the carrier comprises a metal plate or an insulation plate and the metal plate comprises a resin coated copper plate.

11. The embedded chip package process of claim 1, wherein the cover plate comprises a metal plate or an insulation plate and the second circuit layer comprises a patterned resin coated copper layer.

12. The embedded chip package process of claim 1, wherein the step of forming the solder material layer comprises plating tin or printing solder paste.

13. A circuit substrate with embedded device, comprising:
a substrate, comprising a first circuit layer, a dielectric layer and a second circuit layer, wherein the first circuit layer and the second circuit layer are located on the two opposite surfaces of the dielectric layer, and the dielectric layer has a conductive through hole electrically connecting the first circuit layer and the second circuit layer;
an embedded device, embedded within the dielectric layer and electrically connected to the first circuit layer; and
a shielding layer, covering: a surface of the dielectric layer facing the embedded device.

14. The circuit substrate with embedded device of claim 13, wherein the first circuit layer has a first contact correspondingly disposed at one end of the conductive through hole and the second circuit layer has a second contact correspondingly disposed at the other end of the conductive through hole, and the first contact and the second contact are electrically connected through the conductive through hole.

15. The circuit substrate with embedded device of claim 13, wherein the shielding layer comprises a copper layer.

16. The circuit substrate with embedded device of claim 13, wherein the shielding layer comprises a metallic glass layer, a tin layer or a wave-absorbing material layer.

17. The circuit substrate with embedded device of claim 13, wherein the shielding layer and the second circuit layer are made of metallic material.

18. The circuit substrate with embedded device of claim 13, wherein the embedded device comprises a chip having at least a bump and the first circuit layer has a corresponding bonding pad electrically connected to the bump.

19. The circuit substrate with embedded device of claim 13, wherein the embedded device comprises a capacitor, a resistor or an inductor.
